(19) United States
(12) Patent Application Publication
(10) Pub. No.: US 2018/0179662 A1
(43) Pub. Date: Jun. 28, 2018

(54) METHOD FOR CONTROLLING VAPOR PHASE GROWTH APPARATUS

(71) Applicant: NuFlare Technology, Inc., Kanagawa (JP)

(72) Inventors: Hideshi TAKAHASHI, Yokohama-shi (JP); Yuusuke SATO, Tokyo (JP)

(21) Appl. No.: 15/850,064

(22) Filed: Dec. 21, 2017

(30) Foreign Application Priority Data
Dec. 22, 2016 (JP) 2016-248713

(51) Int. Cl. C30B 25/16; C30B 25/10

(52) U.S. Cl. CPC C30B 25/16; C30B 25/10

(57) ABSTRACT

According to an aspect of the invention, there is provided a method for controlling a vapor phase growth apparatus, the vapor phase growth apparatus including a first reactor and a second reactor, a first substrate being processed in the first reactor, a second substrate being processed in the second reactor, the method including suppling a gas including a first source gas including organic metal, a second source gas including a group V element and a dilution gas to the first reactor and the second reactor at a predetermined flow rate, the first source gas, the second source gas and the dilution gas being supplied from gathered gas sources, respectively, rotating the first substrate and the second substrate at a predetermined rotational speed to form films, the method including: in the first reactor, supplying the first source gas, the second source gas and the dilution gas to form the films; in the second reactor, supplying the dilution gas without supplying the first source gas; and stopping forming the films.

### CROSS-REFERENCE TO RELATED APPLICATION

This application is based upon and claims the benefit of priority from Japanese Patent Application No. 2016-248713, filed on Dec. 22, 2016, the entire contents of which are incorporated herein by reference.

### FIELD OF THE INVENTION

Embodiments described herein relate generally to a method for controlling a vapor phase growth apparatus.

### BACKGROUND OF THE INVENTION

As a method for forming a high-quality semiconductor film, there is an epitaxial growth technique which grows a single-crystal film on a substrate (wafer), using vapor phase growth.

In a vapor phase growth method and a vapor phase growth apparatus using the epitaxial growth technique, a substrate is supported by a supporter in a reactor which is maintained at normal pressure or reduced pressure and is heated. Then, reaction gas which is a source of a film is supplied onto the substrate. For example, the thermal reaction of reaction gas occurs in the surface of the substrate and an epitaxial single-crystal film is formed on the surface of the substrate.

In a compound semiconductor device, such as a light emitting diode (LED) or a high electron mobility transistor (HEMT), it is necessary to form a multi-layer film with high throughput. Therefore, a method has been used which controls a plurality of reactors under the same conditions at the same time in order to form films on a plurality of substrates at the same time.

### SUMMARY OF THE INVENTION

According to an aspect of the invention, there is provided a method for controlling a vapor phase growth apparatus, the vapor phase growth apparatus including, a first reactor processing a first substrate, a second reactor processing a second substrate, a gas feeder including an unified first gas line to supply a first source gas including organic metal, an unified second gas line to supply a second source gas including a group V element and a dilution gas source to supply a dilution gas, the gas feeder supplying each gas to the first reactor and the second reactor at a predetermined flow rate, respectively, rotors to rotate the first substrate and the second substrate at a predetermined rotational speed to form films, respectively, heaters to heat the first substrate and the second substrate at a predetermined temperature, respectively, the method comprising: supplying the first source gas, the second source gas and the dilution gas to the first reactor, to form the film; and supplying the dilution gas without supplying the first source gas to the second reactor, to stop forming the film.

### BRIEF DESCRIPTION OF THE DRAWINGS

FIG. 1 is a diagram illustrating the configuration of a vapor phase growth apparatus according to a first embodiment;

FIG. 2 is a cross-sectional view schematically illustrating a reactor according to the first embodiment;

FIG. 3 is a flowchart illustrating a method for controlling the vapor phase growth apparatus according to the first embodiment; and

FIG. 4 is a flowchart illustrating a method for controlling a vapor phase growth apparatus according to a second embodiment.

### DETAILED DESCRIPTION OF THE EMBODIMENTS

### First Embodiment

Hereinafter, an embodiment of the invention will be described with reference to the drawings.

In the specification, the direction of gravity in a state in which a vapor phase growth apparatus is provided so as to form a film is defined as a “lower” direction and a direction opposite to the direction of gravity is defined as an “upper” direction. Therefore, a “lower portion” means a position in the direction of gravity relative to the reference and a “lower side” means the direction of gravity relative to the reference. In addition, an “upper portion” means a position in the direction opposite to the direction of gravity relative to the reference and an “upper side” means the direction opposite to the direction of gravity relative to the reference. Furthermore, a “longitudinal direction” is the direction of gravity.

According to this embodiment, there is provided a method for controlling a vapor phase growth apparatus, the vapor phase growth apparatus including a first reactor and a second reactor, a first substrate being processed in the first reactor, a second substrate being processed in the second reactor, the method including suppling a gas including a first source gas including organic metal, a second source gas including a group V element and a dilution gas to the first reactor and the second reactor at a predetermined flow rate, the first source gas, the second source gas and the dilution gas being supplied from gathered gas sources, respectively, rotating the first substrate and the second substrate at a predetermined rotational speed to form films, the method including: in the first reactor, supplying the first source gas, the second source gas and the dilution gas to form the films; in the second reactor, supplying the dilution gas without supplying the first source gas; and stopping forming the films.

According to the method for controlling a vapor phase growth apparatus of this embodiment, when any one of a plurality of reactors is not available due to, for example, a failure, it is possible to prevent the waste of process gas while preventing the backward flow of, for example, a reaction product and residual gas from the exhaust mechanism to the unavailable reactor.

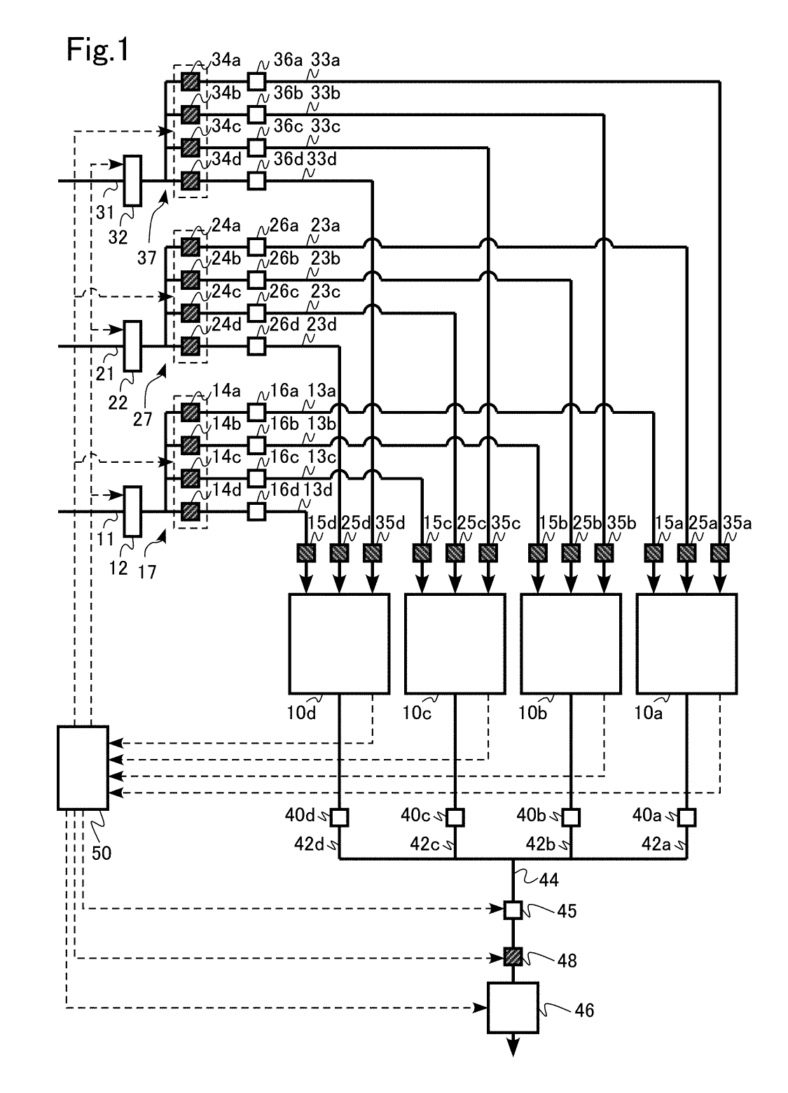

FIG. 1 is a diagram illustrating the configuration of the vapor phase growth apparatus according to this embodiment. The vapor phase growth apparatus according to this embodiment is, for example, an epitaxial growth apparatus using a metal organic chemical vapor deposition method (MOCVD method). Hereinafter, an example in which gallium nitride (GaN) is epitaxially grown will be mainly described.

The vapor phase growth apparatus according to this embodiment includes four reactors 10a, 10b, 10c, and 10d. Each of the four reactors is, for example, a vertical single wafer type epitaxial growth apparatus. The number of reactors is not limited to 4 and may be an arbitrary value equal to or greater than 2. The number of reactors can be represented by n (n is an integer equal to or greater than 2). Hereinafter, “10a, 10b, 10c, 10d” is represented by “10a to 10d”.

The vapor phase growth apparatus according to this embodiment includes three main gas supply paths, that is, a first main gas supply path 11, a second main gas supply path 21, and a third main gas supply path 31 that supply process gas to the four reactors 10a to 10d.

For example, the first main gas supply path 11 supplies unified source gas including organic metal gas, which is a group-III element gas, and carrier gas to the reactors 10a to 10d.

The group-III element is, for example, gallium (Ga), aluminum (Al), or indium (In). In addition, the organic metal is, for example, trimethylgallium (TMG), trimethylaluminum (TMA), or trimethylindium (TMI). Gas including TMG is a source gas of Ga. Gas including TMA is a source gas of Al. In addition, gas including TMI is a source gas of In.

The carrier gas is, for example, hydrogen gas. A compensation gas line (not illustrated) is provided in the first main gas supply path 11. The compensation gas is, for example, hydrogen gas.

A first main mass flow controller 12 is provided in the first main gas supply path 11. The first main mass flow controller 12 controls the flow rate of a first process gas through the first main gas supply path 11.

In addition, a branch portion 17 that branches the first main gas supply path 11 is provided. The first main gas supply path 11 is branched into four first sub-gas supply paths, that is, a first sub-gas supply path 13a, a second sub-gas supply path 13b, a third sub-gas supply path 13c, and a fourth sub-gas supply path 13d by the branch portion 17 on the downstream side of the first main mass flow controller 12. The branched first process gas is supplied to the corresponding reactors 10a to 10d through the first to fourth sub-gas supply paths 13a to 13d, respectively.

First stop valves 14a to 14d that can stop the flow of the source gas are provided in the sub-gas supply paths 13a to 13d, respectively. When a failure occurs in any one of the four reactors 10a to 10d, the first stop valves 14a to 14d have a function of stopping the flow of the process gas to the reactor in which the failure has occurred.

The first stop valves 14a to 14d are disposed at positions adjacent to the branch portion 17 on the downstream side of the branch portion 17 such that the distance to the branch portion 17 is less than the distance to the reactors 10a to 10d.

Second stop valves 15a to 15d that can stop the flow of the first source gas are provided at positions adjacent to the four reactors 10a to 10d on the downstream side of the first stop valves 14a to 14d, respectively. For example, when the reactors 10a to 10d are open to the air for maintenance, the second stop valves 15a to 15d are closed such that the upstream side is not exposed to the air.

Four sub-mass flow controllers 16a to 16d that control the flow rate of the first process gas through the sub-gas supply paths 13a to 13d are provided between the first stop valves 14a to 14d and the second stop valves 15a to 15d, respectively.

The second main gas supply path 21 supplies, for example, dilution gas to the reactors 10a to 10d. The dilution gas is, for example, hydrogen gas.

A second main mass flow controller 22 is provided in the second main gas supply path 21. The second main mass flow controller 22 controls the flow rate of a second process gas through the second main gas supply path 21.

Similarly to the first main gas supply path 11, a branch portion 27, sub-gas supply paths 23a to 23d, first stop valves 24a to 24d, second stop valves 25a to 25d, and sub-mass flow controllers 26a to 26d are provided in the second main gas supply path 21.

The third main gas supply path 31 supplies, for example, unified source gas including ammonia gas to the reactors 10a to 10d. The ammonia gas is a source gas of nitrogen (N) which is a group-V element.

A compensation gas line is provided in the third main gas supply path 31. Compensation gas is, for example, hydrogen gas.

A third main mass flow controller 32 is provided in the third main gas supply path 31. The third main mass flow controller 32 controls the flow rate of a third process gas through the third main gas supply path 31.

Similarly to the first main gas supply path 11, a branch portion 37, sub-gas supply paths 33a to 33d, first stop valves 34a to 34d, second stop valves 35a to 35d, and sub-mass flow controllers 36a to 36d are provided in the third main gas supply path 31.

The vapor phase growth apparatus according to this embodiment includes sub-gas exhaust paths 42a to 42d through which gas is exhausted from the reactors 10a to 10d. In addition, the vapor phase growth apparatus includes a main gas exhaust path 44 where the sub-gas exhaust paths 42a to 42d are joined. An exhaust mechanism 46 for sucking gas is provided in the main gas exhaust path 44. The exhaust mechanism 46 is, for example, a known vacuum pump. With this configuration, exhaust gas from the reactors 10a to 10d is gathered and exhausted through one path. In addition, the aspect in which the exhaust gas is gathered and exhausted through one path is not limited to the above-mentioned aspect.

Filters 40a to 40d are provided in the sub-gas exhaust paths 42a to 42d, respectively, if necessary. A pressure adjustment portion 45 is provided in the main gas exhaust path 44 and controls the amount of gas exhausted. The pressure adjustment portion 45 is, for example, a throttle valve. In addition, a third stop valve 48 is provided between the pressure adjustment portion 45 and the exhaust mechanism 46.

A control unit 50 controls the main mass flow controllers 12, 22, and 32, the sub-mass flow controllers 16a to 16d, 26a to 26d, and 36a to 36d, the first stop valves 14a to 14d, 24a to 24d, and 34a to 34d, the second stop valves 15a to 15d, 25a to 25d, and 35a to 35d, the pressure adjustment portion 45, and the third stop valve 48. In addition, the control unit 50 controls the rotation of a substrate W by a rotating mechanism 74, which will be described below, the heating of the substrate W by a heating unit 64, the exhaust of a reaction product and residual gas by the exhaust mechanism 46, the loading and unloading of the substrate W to and from the reactors 10a to 10d by a handling arm, and the attachment and detachment of the substrate W to and from a supporter 62.

In addition, the control unit 50 determines whether it is necessary to stop the flow of the process gas on the basis of the detection result of a failure in any one of the four reactors 10a to 10d. When it is determined that it is necessary to stop the flow of the process gas, the control unit 50 controls the first stop valves such that the flow of the process gas to the reactor from which the failure has been detected is stopped. In addition, the control unit 50 calculates the total flow rate of the process gas supplied to the reactors other than the reactor from which the failure has been detected and controls the main mass flow controllers 12, 22, and 32 on the basis of the calculated total flow rate.

Furthermore, the control unit 50 controls the vapor phase growth conditions of the four reactors 10a to 10d such that the vapor phase growth conditions are the same.

The control unit 50 is, for example, an electronic circuit. The control unit 50 is, for example, a computer which is a combination of hardware, such as an arithmetic circuit, and software, such as a program.

The control unit 50 may be hardware, such as an electric circuit or a quantum circuit, or software. When the control unit 50 is software, a microprocessor, such as a central processing unit (CPU), a read only memory (ROM) that stores a processing program, a random access memory (RAM) that temporarily stores data, an input/output port, and a communication port may be used. A recording medium is not limited to a detachable recording medium, such as a magnetic disk or an optical disk, and may be a fixed recording medium, such as a hard disk device or a memory.

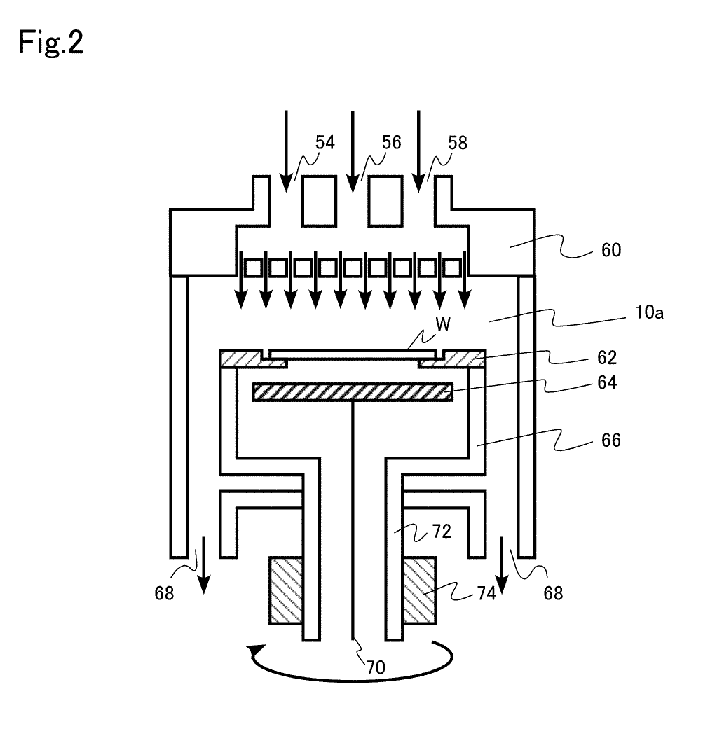

FIG. 2 is a cross-sectional view schematically illustrating the reactor according to this embodiment.

The vapor phase growth apparatus includes, for example, the reactors 10a to 10d which are cylindrical hollow bodies made of stainless steel. The vapor phase growth apparatus includes shower plates 60 that are provided in upper parts of the reactors 10a to 10d and supply the process gas into the reactors 10a to 10d. Gas supply portions 54, 56, and 58 for supplying, for example, the process gas or cleaning gas into the reactors 10a to 10d are provided in an upper part of the shower plate 60. The gas supply portions 54 are connected to the second stop valves 15a to 15d. The gas supply portions 56 are connected to the second stop valves 25a to 25d. The gas supply portions 58 are connected to the second stop valves 35a to 35d.

In addition, a supporter 62 on which the substrate W can be placed is provided below the shower plate 60 in each of the reactors 10a to 10d. The supporter 62 may be, for example, a ring-shaped holder that has an opening at the center as illustrated in FIG. 2 or a susceptor having a structure that comes into contact with substantially the entire rear surface of the substrate W.

The vapor phase growth apparatus includes a rotating unit 66 that has an upper surface on which the supporter 62 is disposed and rotates the supporter 62. A heater as the heating unit 64 that heats the substrate W placed on the supporter 62 is provided below the supporter 62.

A rotating shaft 72 of the rotating unit 66 is connected to a rotating mechanism 74 that is provided in a lower part of the rotating shaft 72. The rotating mechanism 74 can rotate the substrate W on its center at a speed that is, for example, equal to or greater than 50 rpm and equal to or less than 2000 rpm.

A vacuum sealing member is provided between the rotating shaft 72 and the bottom of each of the reactors 10a to 10d.

The heating unit 64 is provided so as to be fixed in the rotating unit 66. Power is supplied to the heating unit 64 through an electrode 70 that passes through the rotating shaft 72. In addition, a push up pin (not illustrated) that passes through the heating unit 64 is provided in order to attach and detach the substrate W to and from the supporter 62.

The vapor phase growth apparatus further includes gas exhaust portions 68 which are exhaust mechanisms for exhausting a reaction product obtained by the reaction of the source gas on, for example, the surface of the substrate W and gas remaining in the reactors 10a to 10d from the reactors 10a to 10d and are provided at the bottoms of the reactors 10a to 10d. The gas exhaust portions 68 are connected to the filters 40a to 40d.

In addition, substrate loading/unloading ports and gate valves (not illustrated) through which the substrate is transferred are provided. The substrate W can be transferred between load lock chambers (not illustrated) and the reactors 10a to 10d which are connected to each other by the gate valves by a handling arm. Here, for example, the handling arm made of synthetic quartz can be inserted into a space between the shower plate 60 and the supporter 62.

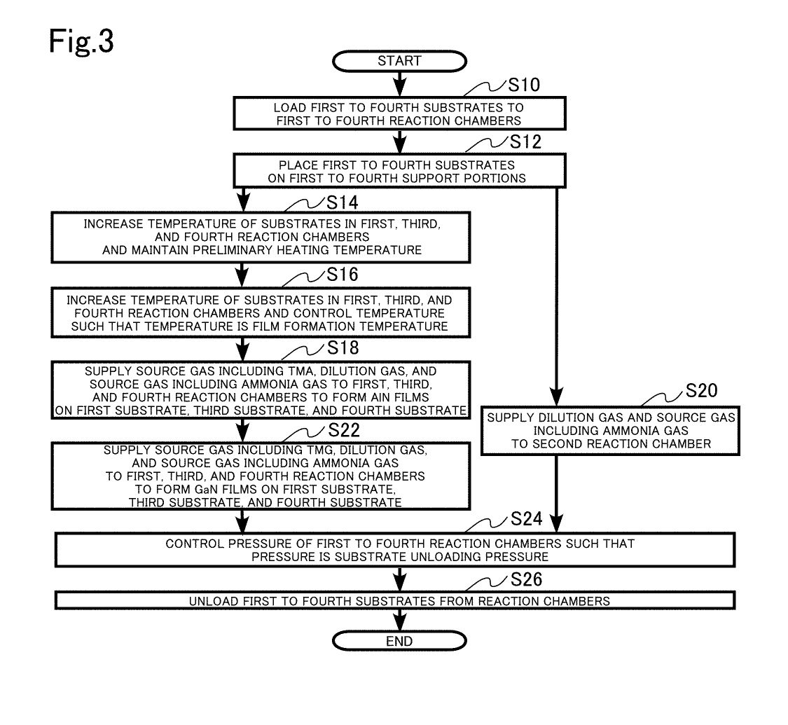

FIG. 3 is a flowchart illustrating a method for controlling the vapor phase growth apparatus according to this embodiment.

Next, an example in which GaN is epitaxially grown by a vapor phase growth method according to this embodiment will be described. It is assumed that the operation of the reactor 10b is stopped due to, for example, a failure and the reactors 10a, 10c, and 10d are used to forma GaN film formation. Hereinafter, each step can be controlled by the control unit 50. However, each step may be directly controlled by an operator.

First, substrates are loaded to each of the reactors 10a to 10d (S10). Here, the substrate loaded to the reactor 10b is a dummy substrate. Each substrate and the dummy substrate are, for example, silicon (Si) wafers.

When the substrates are loaded, for example, the gate valves (not illustrated) in the substrate loading/unloading ports of the reactors 10a to 10d are opened and each substrate and the dummy substrate in the load lock chambers (not illustrated) are transferred into the reactors 10a to 10d by the handling arm (not illustrated).

Then, each substrate or the dummy substrate is placed on the supporters 62 provided in the reactors 10a to 10d (S12).

For example, each substrate and the dummy substrate are placed on the supporters 62 by the push up pins (not illustrated). The handling arm is returned to the load lock chamber and the gate valve is closed.

Then, dilution gas, such as hydrogen (H₂) gas or nitrogen (N₂) gas, is introduced into each reactor by the first main gas supply path 11, the second main gas supply path 21, and the third main gas supply path 31 and the exhaust mechanism 46 is operated such that pressure is reduced to film formation start pressure by the pressure adjustment portion 45.

Then, the heating power of the heating unit 64 in each of the reactors 10a, 10c, and 10d is increased to increase the temperature of a first substrate, a third substrate, and a fourth substrate and the temperature is maintained at a preliminary heating temperature (S14). The temperature of the substrate can be measured by, for example, a radiation thermometer. In this case, the temperature of the second substrate is not increased.

After a native oxide is removed by baking, the temperature of the first substrate, the third substrate, and the fourth substrate is controlled by the heating unit 64 such that the temperature is a film formation temperature that is, for example, equal to or greater than 600° C. and equal to or less than 1100° C. while the first substrate, the third substrate, and the fourth substrate are rotated at a predetermined rotational speed (for example, 900 rpm), if necessary (S16). In contrast, the second substrate (dummy substrate) is rotated at a low speed (for example, 50 rpm) and the temperature of the second substrate is not increased.

Then, source gas including TMA which has hydrogen gas as carrier gas is supplied from the first main gas supply path 11 to the reactors 10a, 10c, and 10d.

The flow rate of the source gas including TMA which has hydrogen gas as carrier gas is controlled by the first main mass flow controller 12 and the source gas is branched and supplied to the sub-gas supply paths 13a, 13c, and 13d branched from the first main gas supply path 11 and is introduced into the reactors 10a, 10c, and 10d except the reactor 10b.

At the same time, hydrogen gas is supplied from the second main gas supply path 21 to the reactors 10a to 10d and source gas including ammonia gas is supplied from the third main gas supply path 31 to the reactors 10a to 10d.

The flow rate of the gas including ammonia is controlled by the third main mass flow controller 32 and the gas is supplied to the sub-gas supply paths 33a to 33d branched from the third main gas supply path 31 and is introduced into all of the reactors including the reactor 10b.

In this way, the source gas including TMA, dilution gas, and the source gas including ammonia gas are supplied to the reactors 10a, 10c, and 10d to form an aluminum nitride (AlN) film on the first substrate, the third substrate, and the fourth substrate (S18). The thickness of the AlN film is, for example, equal to or greater than 100 nm and equal to or less than 300 nm. Dilution gas and the source gas including ammonia gas are supplied to the reactor 10b (S20).

Then, as in the formation of the AlN film, source gas including TMG which has hydrogen gas as carrier gas, source gas including ammonia gas, and dilution gas (for example, hydrogen gas) are supplied to the reactors 10a, 10c, and 10d to form a gallium nitride (GaN) film on each substrate (S22). In contrast, the dilution gas and the source gas including ammonia gas are continuously supplied to the reactor 10b (S20).

As such, TMA or TMG having hydrogen gas as carrier gas, dilution gas, and gas including ammonia are supplied to the reactors 10a, 10c, and 10d to form an AlN film and a GaN film (S18 and S22). While the films are being formed, dilution gas and source gas including ammonia gas are supplied to the reactor 10b (S20).

After the formation of the films is completed, the heating power of the heating unit 64 is reduced to decrease the temperature of each substrate to a transferring temperature.

In contrast, the flow of the source gas from each of the first main gas supply path 11 and the third main gas supply path 31 is stopped and dilution gas, such as hydrogen (H₂) gas or nitrogen (N₂) gas, is supplied from the first main gas supply path 11, the second main gas supply path 21, and the third main gas supply path 31.

Then, the pressure adjustment portion 45 controls the internal pressure of the reactors 10a to 10d such that the pressure is a substrate unloading pressure at which the substrate can be unloaded (S24).

Then, each substrate is unloaded from the reactors 10a to 10d (S26).

Next, the function and effect of the method for controlling the vapor phase growth apparatus according to this embodiment will be described.

In the method for controlling the vapor phase growth apparatus according to this embodiment, gas including source gas and dilution gas is supplied to the reactors 10a, 10c, and 10d to form films. At the same time, dilution gas and source gas including ammonia are supplied to the reactor 10b. The source gas and the dilution gas are supplied to the reactors 10a, 10c, and 10d to form films in the reactors 10a, 10c, and 10d. In addition, the dilution gas is supplied to the reactor 10b and is exhausted to prevent the backward flow of a reaction product and residual gas from the reactors 10a, 10c, and 10d through the sub-gas exhaust paths 42a to 42d. In addition, since gas including organic metal is not supplied to the reactor 10b, it is possible to prevent the waste of expensive source gas such as TMA or TMG. In addition, only dilution gas may be supplied to the reactor 10b without source gas including V element and only source gas including a group V element, e.g. ammonia gas, may be supplied to the reactor 10b without dilution gas.

As such, according to the method for controlling the vapor phase growth apparatus according to this embodiment, it is possible to provide a vapor phase growth apparatus control method that can prevent the waste of the source gas of a film while preventing the backward flow of gas from the exhaust mechanism.

### Second Embodiment

A method for controlling a vapor phase growth apparatus according to this embodiment includes: supplying cleaning gas including chlorine atoms to the first, third, and fourth reactors; and supplying gas including hydrogen gas or inert gas to the second reactor to perform cleaning. A material including Ga which has been attached to the surfaces of members in the reactor or an inner wall of the reactor is removed by the cleaning. The second embodiment differs from the first embodiment in that cleaning is performed instead of forming films. Here, the description of the same content as that in the first embodiment will not be repeated.

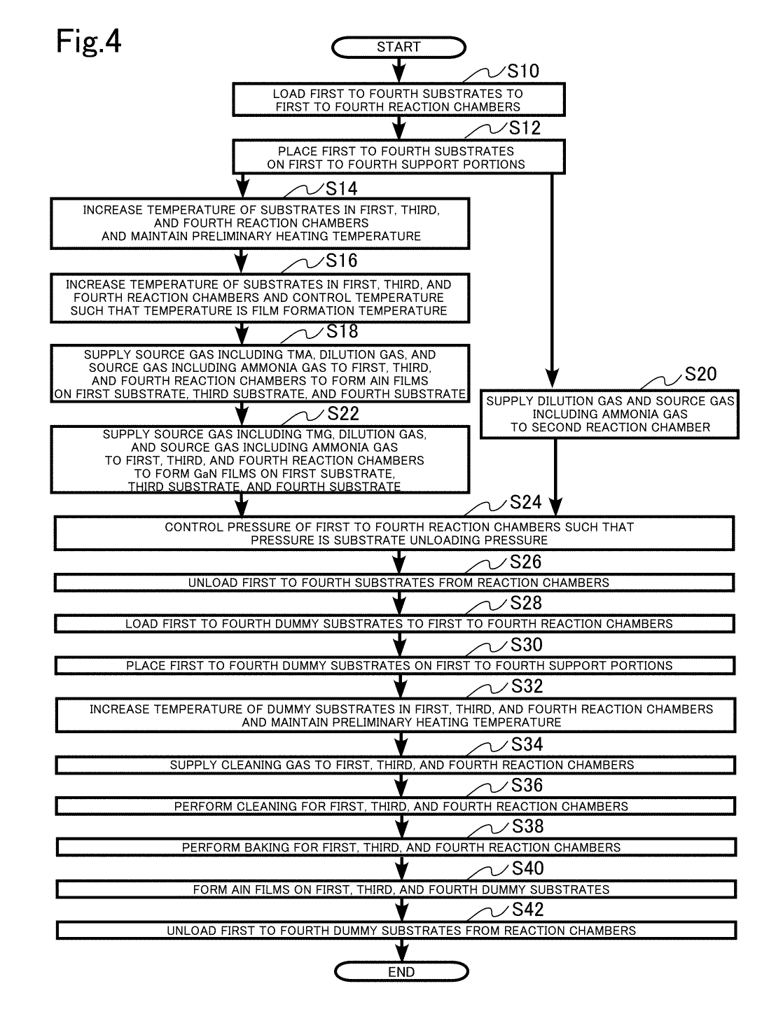

FIG. 4 is a flowchart illustrating a vapor phase growth apparatus control method according to this embodiment.

After each substrate is unloaded from the reactors 10a to 10d (S26) in the first embodiment, each dummy substrate is loaded into the reactors 10a to 10d (S28). The dummy substrate is, for example, a silicon carbide (SiC) substrate.

Then, each dummy substrate is placed on the supporters 62 provided in the reactors 10a to 10d (S30).

Then, the pressure adjustment portion 45 is controlled such that the pressure is changed from a substrate loading pressure to a cleaning pressure.

Then, the heating power of the heating unit 64 in each of the reactors 10a, 10c, and 10d is increased to raise the temperature and the temperature of the dummy substrate is maintained at a preliminary heating temperature (S32).

Then, the heating power of the heating unit 64 in each of the reactors 10a, 10c, and 10d is increased and the temperature of the dummy substrate is controlled such that the temperature is a cleaning temperature that is, for example, equal to or greater than 950° C. and equal to or less than 1050° C. while the dummy substrate is rotated at a predetermined rotational speed. In this case, the heating power of the heating unit 64 in the reactor 10b is not increased.

Then, cleaning gas including chlorine atoms is supplied to the reactors 10a, 10c, and 10d (S34). Then, the reactors 10a, 10c, and 10d of which the temperature has been controlled such that the reactors 10a, 10c, and 10d can be cleaned are cleaned (S36). In this case, the cleaning gas may be supplied into the reactor 10b.

When a GaN film is formed, a reaction product including Ga is attached to portions other than the substrate in the reactor. For example, the reaction product is attached to the surfaces of members other than the substrate or the inner wall of the reactor. Cleaning is performed to remove the reaction product including Ga that has been attached to the surfaces of the members in the reactor 10 or the inner wall of the reactor 10.

The cleaning gas including chlorine atoms is, for example, hydrogen chloride (HCl). However, the cleaning gas may be other kinds of gas. The flow rate of the cleaning gas including chlorine atoms is, for example, equal to or greater than 5% and equal to or less than 15% of the flow rate of hydrogen gas.

It is preferable the cleaning gas including chlorine atoms be supplied by the second main gas supply path 21. The reason is that, when the first main gas supply path 11 is used, the residual chlorine gas reacts with Ga while a GaN film is being formed and hinders the formation of a high-quality GaN film. In addition, the reason is that, when the third main gas supply path 31 is used, the cleaning gas including chlorine atoms reacts with ammonia to generate ammonium chloride (NH₄Cl).

The temperature of the dummy substrate during cleaning is preferably equal to or greater than 950° C. and equal to or less than 1050° C. When the temperature is less than the above-mentioned range, there is a concern that an attached material including Ga will not be sufficiently removed. When the temperature is greater than the above-mentioned range, there is a concern that the surfaces of the members in the reactors 10a, 10c, and 10d or the inner walls of the reactors 10a, 10c, and 10d will be contaminated by the cleaning gas.

When the cleaning is completed, the supply of the cleaning gas is stopped. Then, the heating power of the heating unit 64 is increased to raise the temperature of the dummy substrate to a baking temperature that is, for example, equal to or greater than 1050° C. and equal to or less than 1200° C.

Then, the exhaust of gas by the exhaust mechanism 46 is continuously performed and baking is performed in the reactors 10a, 10c, and 10d while the rotating units 66 are rotated at a low speed (S38). During baking, baking gas is supplied to the reactors 10a to 10d.

During cleaning, there is a concern that a material including chlorine atoms will be attached to the surfaces of the members in the reactors, the inner walls of the reactors, and the inner surfaces of pipes. The attached material including chlorine atoms is, for example, a reaction product including chlorine atoms or an absorbed material of gas including chlorine atoms.

The material including chlorine atoms which has been attached to the surfaces of the members in the reactor 10, the inner wall of the reactor 10, and the inner surfaces of the pipes is removed by baking.

It is preferable that the baking gas be hydrogen gas in order to remove an attached material including Ga in addition to an attached material including chlorine atoms. In addition, instead of the hydrogen gas, inert gas, such as nitrogen gas, may be used.

The temperature of the dummy substrate during baking is preferably equal to or greater than 1050° C. and equal to or less than 1200° C. When the temperature is less than the above-mentioned range, there is a concern that an attached material including chlorine atoms will not be sufficiently removed. When the temperature is greater than the above-mentioned range, there is a concern that the dummy substrate and the surfaces of the members in the reactor or the inner wall of the reactor will be damaged.

It is preferable that the temperature of the dummy substrate when the baking gas is supplied be greater than the temperature of the dummy substrate when the cleaning gas is supplied. When the baking temperature is greater than the cleaning temperature, the effect of removing the attached material including chlorine atoms is improved. In addition, when the baking gas is hydrogen gas, the effect of removing the attached material including Ga is improved.

After backing is performed for a predetermined period of time, the heating power of the heating unit 64 in each of the reactors 10a, 10c, and 10d is reduced to decrease the temperature of the dummy substrate to a film formation temperature that is, for example, equal to or greater than 600° C. and equal to or less than 1100° C.

In addition, source gas including TMA, dilution gas, and gas including ammonia may be supplied to the reactors 10a, 10c, and 10d to form an aluminum nitride (AlN) film on the dummy substrate (S40). In this case, dilution gas, or dilution gas and gas including ammonia are supplied to the reactor 10b.

The surface of the attached material including chlorine atoms on the surfaces of the members in the reactor 10 or the inner wall of the reactor 10 which has not been removed by baking is covered with the AlN film. In addition, instead of the AlN film, a silicon nitride (SiN) film may be formed.

The thickness of the AlN film is preferably equal to or greater than 10 nm and equal to or less than 50 nm. When the thickness is less than the above-mentioned range, there is a concern that the attached material including chlorine atoms will not be sufficiently covered. When the thickness is greater than the above-mentioned range, the time required to form the AlN film increases and the proportion of the cleaning processing time using the dummy substrate to the total film formation time increases. As a result, there is a concern that the throughput of film formation will be reduced.

In particular, it is preferable that the thickness of the AlN film formed on the dummy substrate be less than the thickness of the AlN film formed on the first substrate, the third substrate, and the fourth substrate in order to reduce the cleaning processing time using the dummy substrate.

Then, each dummy substrate is unloaded from the reactors 10a to 10d (S42).

According to the vapor phase growth apparatus control method of this embodiment, it is possible to provide a vapor phase growth apparatus control method that can prevent the backward flow of cleaning gas and baking gas from the exhaust mechanism 46.

The embodiments of the invention have been described above with reference to examples. The above-described embodiments are illustrative examples and do not limit the invention. In addition, the components according to each embodiment may be appropriately combined with each other.

For example, in the above-described embodiments, the example in which the AlN and GaN single-crystal films are formed has been described. However, for example, the invention can be applied to form other group III-V nitride-based semiconductor single-crystal films, such an aluminum gallium nitride (AlGaN) film and an indium gallium nitride (InGaN) film. Furthermore, the invention can be applied to a group III-V semiconductor such as GaAs.

In addition, the example in which one kind of organic metal, that is, TMG is used has been described. However, two or more kinds of organic metal may be used as a source of a group-III element. In addition, the organic metal may be elements other than the group-III element.

The example in which hydrogen gas (H₂) is used as the carrier gas and the dilution gas has been described above. However, nitrogen gas (N₂), argon gas (Ar), helium gas (He), or combinations thereof may be applied as the carrier gas.

The process gas may be, for example, a mixed gas including both a group-III element and a group-V element.

For example, in the above-described embodiments, the vertical single wafer type epitaxial apparatus in which n reactors are used to form films on each substrate has been described as an example. However, the application of the n reactors is not limited to the single-wafer epitaxial apparatus. For example, the invention may be applied to a horizontal epitaxial apparatus or a planetary CVD apparatus that simultaneously forms films on a plurality of wafers which rotate on their own axes while revolving around the apparatus.

In the above-described embodiments, for example, portions which are not directly necessary to describe the invention, such as the configuration of the apparatus or a manufacturing method, are not described. However, the necessary configuration of the apparatus or a necessary manufacturing method can be appropriately selected and used. In addition, all of the vapor phase growth apparatuses and the vapor phase growth methods which include the components according to the invention and whose design can be appropriately changed by those skilled in the art are included in the scope of the invention. The scope of the invention is defined by the scope of the claims and the scope of equivalents thereof.

What is claimed is:

1. A method for controlling a vapor phase growth apparatus, the vapor phase growth apparatus including,
a first reactor processing a first substrate,
a second reactor processing a second substrate,
a gas feeder including an unified first gas line to supply a first source gas including organic metal, an unified second gas line to supply a second source gas including a group V element and a dilution gas source to supply a dilution gas, the gas feeder supplying each gas to the first reactor and the second reactor at a predetermined flow rate, respectively,
rotors to rotate the first substrate and the second substrate at a predetermined rotational speed to form films, respectively,
heaters to heat the first substrate and the second substrate at a predetermined temperature, respectively,
the method comprising:
supplying the first source gas, the second source gas and the dilution gas to the first reactor, to form the film; and
supplying the dilution gas without supplying the first source gas to the second reactor, to stop forming the film.

2. The method for controlling a vapor phase growth apparatus according to claim 1, further comprising:
exhausting an exhaust gas gathered from the first reactor and the second reactor through unified path.

3. The method for controlling a vapor phase growth apparatus according to claim 1
wherein the second source gas includes ammonia gas, and both the dilution gas and the ammonia gas are supplied to the second reactor to stop forming the film.

4. The method for controlling a vapor phase growth apparatus according to claim 1,
wherein the dilution gas includes hydrogen gas.

5. The method for controlling a vapor phase growth apparatus according to claim 1,
wherein the dilution gas includes inert gas.

6. The method for controlling a vapor phase growth apparatus according to claim 1, further comprising:
rotating the second substrate at a speed lower than the predetermined rotational speed, after stopping forming the film.

7. The method for controlling a vapor phase growth apparatus according to claim 1,
wherein, in the second reactor, stopping heating the second reactor after stopping forming the film.

8. The method for controlling a vapor phase growth apparatus according to claim 1, further comprising:
unloading the first substrate from the first reactor,
supplying a cleaning gas including chlorine atoms to the first reactor and supplying the inert gas to the second reactor after unloading.

9. The method for controlling a vapor phase growth apparatus according to claim 8, further comprising:
stopping supplying the cleaning gas to the first reactor, and
supplying a baking gas including hydrogen gas to the first reactor, and the inert gas to the second reactor.

10. The method for controlling a vapor phase growth apparatus according to claim 8, further comprising:
stopping supplying the baking gas to the first reactor; and
supplying gases including the first source gas, the dilution gas and ammonia to the first reactor, and the dilution gas to the second reactor.
